(19) United States
(12) Patent Application Publication
(10) Pub. No.: US 2019/0378768 A1
(43) Pub. Date: Dec. 12, 2019

(54) DISPLAY PANEL PRODUCING SYSTEM AND METHOD OF PRODUCING DISPLAY PANEL

(71) Applicant: SHARP KABUSHIKI KAISHA, Sakai City (JP)

(72) Inventor: KOHICHI TORIUMI, Sakai City (JP)

(21) Appl. No.: 16/433,630

(22) Filed: Jun. 6, 2019

Related U.S. Application Data
(60) Provisional application No. 62/683,638, filed on Jun. 12, 2018.

(51) Int. Cl. H01L 21/66; H01L 51/00; H01L 51/56; H01L 27/32; G02F 1/13

(52) U.S. Cl. CPC H01L 22/12; H01L 51/0005; G02F 1/1306; H01L 27/3241; H01L 51/56

(57) ABSTRACT

A display panel producing system for producing a display panel including a substrate on which films are laminated includes a measuring device, an ink-jet coating device, and a control device. The measuring device is configured to measure an uneven shape of a front face of the substrate in production. The ink-jet coating device is configured to apply a film formation material with an ink-jet technology to form the films on the substrate. The control device is configured to control the measuring device and the ink-jet coating device. The control device controls the measuring device to measure the uneven shape for formation of the films by the ink-jet coating device and to determine a control target for the formation of the films by the ink-jet coating device appropriate for the substrate on which measurement of the uneven shape is performed based on a result of the measurement.

### CROSS REFERENCE TO RELATED APPLICATION

This application claims priority from U.S. Provisional Application No. 62/683,638 filed on Jun. 12, 2018. The entire contents of the priority application are incorporated herein by reference.

### TECHNICAL FIELD

The technology described herein relates to a display panel producing system and a method of producing a display panel including a substrate on which films are laminated.

### BACKGROUND ART

A display panel such as a liquid crystal panel and an organic electro luminescence (EL) panel is mainly composed of a substrate on which a plurality of films is laminated. During manufacturing of the display panel as above, film formation is occasionally performed to the substrate in production with a material of lower viscosity. In such a case, an ink-jet coating device described in Patent Literature 1 (Japanese Patent Application Publication No. 2005-262089) as under is used to coat the substrate in production with a film formation material by an ink-jet process.

The substrate in production includes projections and depressions on its front face because a plurality of films is laminated thereon. In addition, such as contact holes for connecting an upper layer and lower layer of the laminated films or ribs for regulating a direction of liquid crystal molecules are formed. This also leads to unevenness of the front face of the substrate in production. When film formation is performed to the uneven substrate with the ink-jet technology during manufacturing of the display panel, unevenness in film thickness occurs around the projections and the depressions on the substrate if ink-jet coating is performed by a given amount of droplets to given positions (at given intervals), leading to non-uniform display on the display panel. Such a drawback may arise.

Moreover, the ink-jet coating is currently performed during manufacturing of the display panel while an amount or positions of droplets to be applied are determined under the assumption that a surface as a base is made in a designed shape. On the other hand, some deviation in design is present with respect to the surface of the substrate prior to the ink-jet coating, also leading to unevenness in film thickness around the projections and depressions on the substrate.

### SUMMARY

The technology described herein was made in view of the above circumstances. An object is to obtain suppressed unevenness in thickness of a film formed with ink-jet coating during producing of a display panel, thereby preventing non-uniform display on the display panel.

(1) In order to solve the above drawbacks, the technology described herein includes a display panel producing system for producing a display panel provided with a substrate on which a plurality of films is laminated. The display panel producing system includes:

a measuring device configured to measure an uneven shape of a front face of the substrate in production; an ink-jet coating device configured to apply a film formation material with an ink-jet technology to form the films on the substrate in the production; and a control device configured to control the measuring device and the ink-jet coating device. The control device controls the measuring device to measure the uneven shape on the front face of the substrate in the production for formation of the films by the ink-jet coating device and to determine a control target for the formation of the films by the ink-jet coating device appropriate for the substrate on which measurement of the uneven shape is performed based on a result of the measurement.

(2) The display panel producing system may have the configuration in addition to the configuration described in (1): the control device controls the measuring device to measure an uneven shape of a front face of the substrate with the films formed thereon by the ink-jet coating device to determine whether the films are properly formed by the ink-jet coating device.

(3) The display panel producing system may have the following configuration in addition to the configuration described in (2): if the films are not properly formed by the ink-jet coating device, the control device corrects the control target for later formation of films by the ink-jet coating device based on a difference between the uneven shape measured on the substrate on which the films are not properly formed and a target uneven shape.

(4) The display panel producing system may have the following configuration in addition to any one of the configurations described in (1) to (3): the control device determines a target coating position of the film formation material with respect to the substrate in the production and a target coating amount at the position based on the result of the measurement by the measuring device and controls the ink-jet coating device based on the target coating position and the target coating amount.

(5) The display panel producing system may have the following configuration in addition to the configuration described in (4): the ink-jet coating device includes a coating head with nozzles for discharging the film formation material; the nozzles discharges the film formation material while the coating head and the substrate in the production travel relative to each other to form the films; and the control device determines at least one of a discharge amount, a discharge position, an interval of discharge for each of the nozzles and a relative traveling speed between the coating head and the substrate in the production in the ink-jet coating device.

(6) The display panel producing system may have the following configuration in addition to any one of the configurations described in (1) to (5): the measuring device includes a level sensor configured to detect a level of a measuring point; and the level sensor is configured to a level of the substrate in the production to determine the uneven shape on the front face of the substrate.

(7) The display panel producing system may have the following configuration in addition to the configuration described in (6): the level sensor is a laser displacement sensor configured to receive laser beams applied to the measuring point and reflected at the measuring point to detect the level of the measuring point.

(8) In order to solve the above drawbacks, the technology described herein includes a method of producing a display panel including a substrate on which films are laminated. The method including:

a measuring step of measuring an uneven shape of a front face of the substrate in production;

a control target determining step of determining a control target formation of the films with an ink-jet technology appropriate for the substrate on which measurement of the uneven shape is performed based on a result of the measurement in the measuring step to form the films on the substrate on which the measurement is performed with the ink-jet technology; and

an ink-jet coating step of coating the substrate in the production with a film formation material by the ink-jet technology based on the control target determined in the control target determining step.

In the display panel producing system and the method of producing the display panel having the configurations described above, measurement of an uneven shape of a front face is performed on every substrate in production. For instance, a thickness of the substrate or a level of the substrate with respect to a reference is measured. Then, a control target for the formation of the films with the ink-jet coating technology is determined based on a result of the measurement. Consequently, with the display panel producing system and the method of producing the display panel having the configurations described above, because positions and depths related to the unevenness of the substrate are recognized prior to the ink-jet coating and the film is formed with the ink-jet coating appropriate for the substrate, the unevenness in film thickness resulting from the uneven shape can be reduced. Moreover, the display panel producing system and the method of producing the display panel described above are suitable for coating with the material of a relatively lower viscosity with the ink-jet technology, such as the case of film formation of alignment films in producing a liquid crystal panel or formation of organic EL layers in producing an organic EL panel.

(9) The method of producing the display panel may have the following configuration in addition to the configuration described in (8):

an inspecting step of measuring an uneven shape of a front face of the substrate with the films formed thereon in the ink-jet coating step to determine whether the films are properly formed by the ink-jet coating device is in the ink-jet coating step; and

the control target determining step includes correcting the control target based on a difference between the uneven shape of the substrate on which the films are not properly formed and a target uneven shape to determine the control target if the inspecting step determines that the films are not properly formed in the ink-jet coating step.

The aspects of the technology described herein suppresses the unevenness in thickness of the film subjected to the film formation by the ink-jet coating during producing of the display panel, and thus prevents non-uniform display on the display panel.

### BRIEF DESCRIPTION OF THE DRAWINGS

FIG. 1 schematically illustrates a display panel producing system according to a first embodiment.

FIG. 2 is a plan view of a liquid crystal panel that is manufactured by the display panel producing system according to the first embodiment.

FIG. 3 is a plan view illustrating a pixel array of the liquid crystal panel in FIG. 2.

FIG. 4 is a sectional view along an A-A line of the pixel array of the liquid crystal panel in FIG. 3.

FIG. 5A schematically illustrates actuation of a measuring device in FIG. 1.

FIG. 5B schematically illustrates actuation of a measuring device in FIG. 1 while a measuring head is moved from a position shown in FIG. 5A.

FIG. 6 is a sectional view of one example of an alignment film formed with a currently-used display panel producing system.

FIG. 7 is a sectional view of another example of an alignment film formed with a currently-used display panel producing system.

FIG. 8 is a flow chart of an alignment film formation program executed by the display panel producing system according to the first embodiment.

FIG. 9 is a side view of a display panel producing system according to a second embodiment.

### DETAILED DESCRIPTION

Embodiments will be described with reference to the drawings. Note that the technical scope of the present invention is not limited to the embodiments described below, and may be exemplified with various modifications and various improved aspects on the basis of the knowledge of those skilled in the art.

### First Embodiment

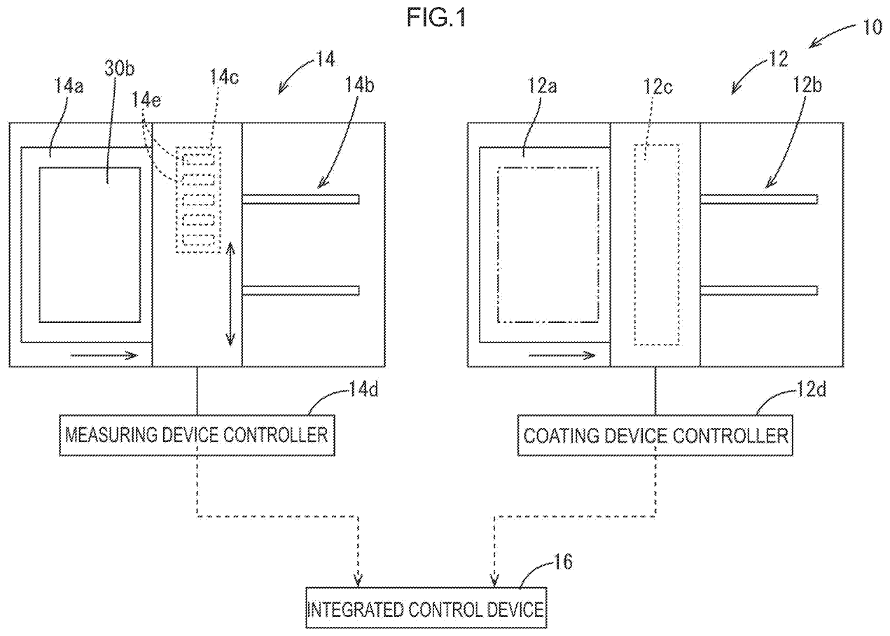

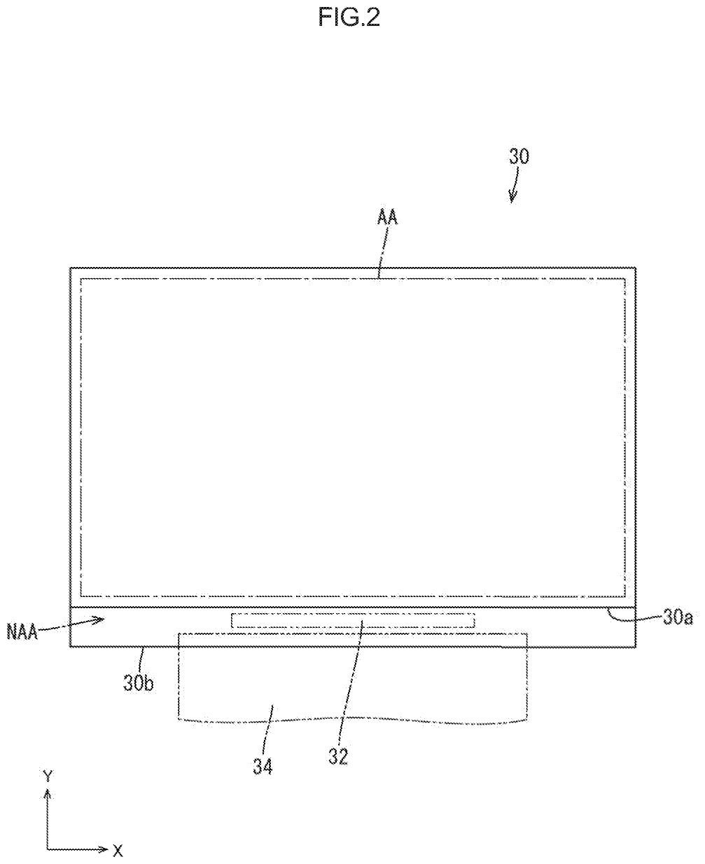

FIG. 1 schematically illustrates a display panel producing system 10 (hereinafter, simply referred to as a “producing system 10” occasionally) as a first embodiment. The producing system 10 includes an ink-jet coating device 12, a measuring device 14, and an integrated control device 16. Briefly, the producing system 10 causes the integrated control device 16 to control the ink-jet coating device 12 and the measuring device 14 integrally, and causes the ink-jet coating device 12 to perform film formation to a substrate so as to conform to an uneven shape on a front face of the substrate measured by the measuring device 14. Before detailed description is made of the producing system 10, a liquid crystal panel 30 as one example of a display panel manufactured by the producing system 10 is to be described in detail with reference to FIGS. 2 to 4.

Configuration of Display Panel

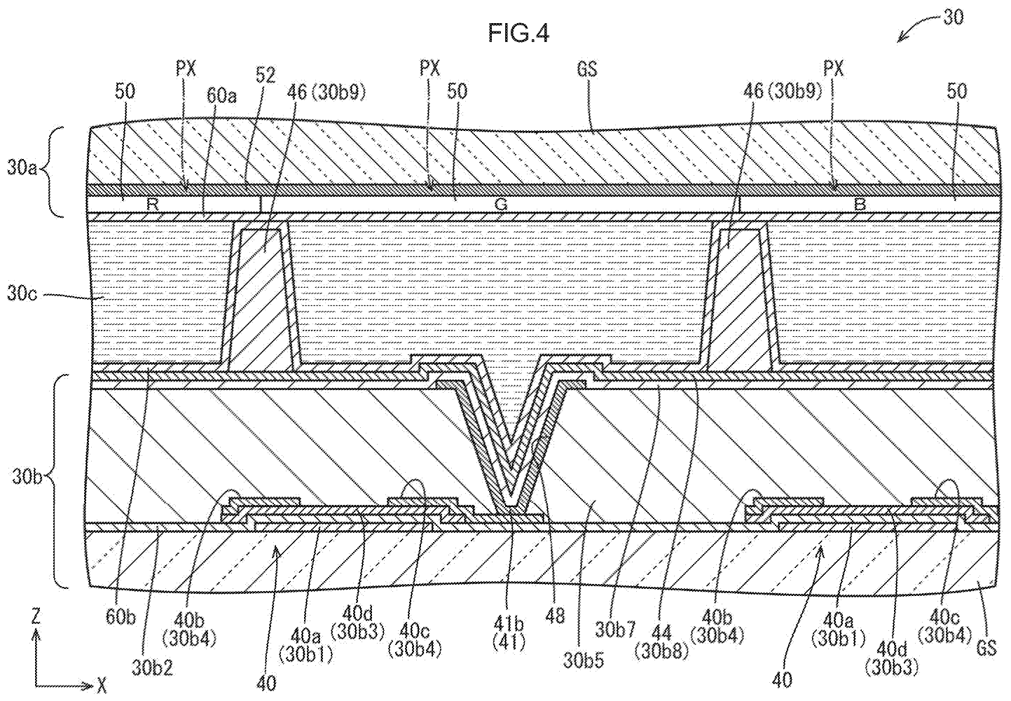

As illustrated in FIG. 2, the liquid crystal panel 30 is horizontally rectangular in its entirety. The liquid crystal panel 30 has a display plate divided into an active area AA where an image is displayed, and a non-active area NAA that surrounds the display area AA in a frame shape (box shape) and includes no image displayed thereon. It should be noted that FIG. 2 illustrates a contour of the display area AA by inner alternate long and short dashed lines, and the non-displayed area NAA external of the inner alternate long and short dashed lines. Note that each of drawings partially indicates an X-axis, a Y-axis, and a Z-axis, each of which is common to the direction among the drawings. The liquid crystal panel 30 has long sides corresponding to the X-axis direction, and short sides corresponding to the Y-axis direction. Moreover, upward and downward directions (front and rear direction) illustrated in FIG. 4 are each a reference, and upper and lower sides therein are occasionally referred to as front and rear sides, respectively.

The liquid crystal panel 30 includes paired substrates 30a, 30b that are substantially transparent with high translucency, and a liquid crystal layer 30c (see FIG. 4). The liquid crystal layer 30c is disposed between the substrates 30a, 30b, and contains liquid crystal molecules of a material whose optical property is variable depending on electric field application. The substrates 30a, 30b are sealed each other via a sealant with a maintained cell gap by a thickness of the liquid crystal layer 30c. A front side (surface side) of the paired substrates 30a, 30b that form the liquid crystal panel 30 is referred to as a CF substrate (opposite substrate) 30a, whereas a rear side (backside) thereof is referred to as an array substrate (TFT substrate, display substrate, active matrix substrate) 30b. The CF substrate 30a and the array substrate 30b each include various films laminated on an internal face of the glass substrate GS. Here, as illustrated in FIG. 2, the array substrate 30b among them is larger than the CF substrate 30a. The array substrate 30b partially extends toward the CF substrate 30a, which extension portion (forming the non-displayed area NAA) has a driver (panel drive unit) 32 and a flexible board (signal transmitting unit) 34 bonded thereon.

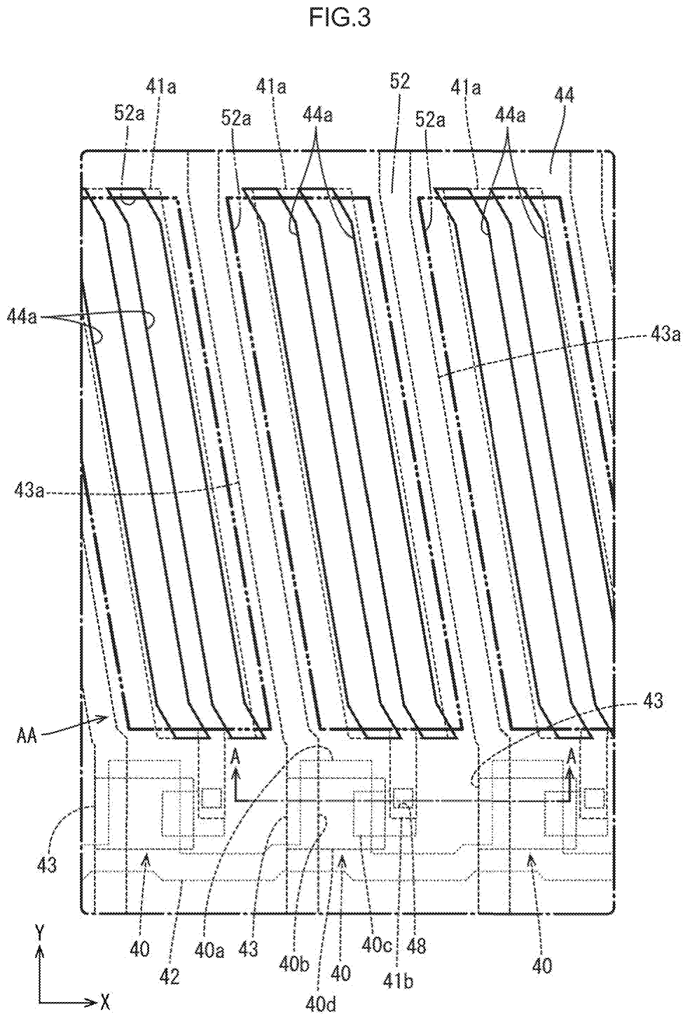

The following describes an interior configuration of the liquid crystal panel 30. As illustrated in FIG. 3, multiple thin film transistors (TFTs) 40 as switching elements and multiple pixel electrodes 41 are arranged in a matrix array (in a row and column manner) on an inner side of the active area AA of the array substrate 30b in the X-axis direction and the Y-axis direction. In addition, gate lines (scanning wirings) 42 and source lines (signal wirings, data wirings) 43 are arranged so as to surround the TFT 40 and the pixel electrodes 41 in a substantially grid shape. The gate lines 42 extend substantially linearly along the X-axis direction. The source lines 43 extend substantially along the Y-axis direction, and each partially include an oblique extension part 43a that extends obliquely with respect to the X-axis direction and the Y-axis direction. The gate lines 42 and the source lines 43 are connected to gate electrodes 40a and source electrodes 40b of the TFTs 40, respectively. The pixel electrodes 41 are connected to drain electrodes 40c of the TFTs 40. The pixel electrode 41 is a substantially parallelogram with a planar longitudinal shape. The source line 43 is interposed between adjacent pixel electrodes 41 along a short side direction (X-axis direction), and the gate line 42 is interposed between adjacent pixel electrodes 41 along a long side direction (Y-axis direction). The pixel electrode 41 has a long side parallel to the oblique extension part 43a of the source line 43.

As illustrated in FIGS. 3 and 4, the active area AA of the array substrate 30B includes the inner side where a common electrode 44 is formed on an upper layer above the pixel electrodes 41 (adjacent to the liquid crystal layer 30c) so as to be superimposed on all the pixel electrodes 41. Almost constant reference electric potential is applied to the common electrode 44, The common electrode 44 extends over the active area substantially entirely. The common electrode 44 has overlapped portions overlapped on the pixel electrodes 41 individually, the overlapped portions each having a plurality of (e.g., two in FIG. 3) longitudinal pixel overlapped openings (pixel overlapped slits, orientation control slits) 44a formed in an opened manner. The pixel overlapped opening 44a extends along the oblique extension part 43a of the source line 43. A potential difference occurs between the pixel electrodes 41 and the common electrode 44 superimposed each other when the pixel electrodes 41 are charged, and accordingly, a fringing field (oblique electric field) is generated between an open edge of the pixel overlapped opening 44a and the pixel electrodes 41. The fringing field includes a normal line component with respect to a plate of the array substrate 30b in addition to a plate component of the array substrate 30b. Using the fringing field allows control of the alignment condition of the liquid crystal molecules in the liquid crystal layer 30c. That is, the liquid crystal panel 30 according to this embodiment operates in a mode referred to as a fringe field switching (FFS) mode.

In contrast to this, as illustrated in FIG. 4, the active area AA of the CF substrate 30a includes an inner side where color filters 50 with three colors of red (R), green (G), and blue (B) are provided. A large number of color filters 50 with different colors are repeatedly arranged along the gate line 42 (X-axis direction), and extend along the source line 43 (Y-axis direction substantially), thereby being arranged generally in a striped shape. The color filters 50 overlap the pixel electrodes 41 adjacent to the array substrate 30b in plan view. The color filters 50 adjacent each other with the different colors in the X-axis direction has boundaries (color boundaries) where the source lines 43 overlap a light-shielding part 52 mentioned later. The liquid crystal panel 30 includes the color filters 50 with the colors of R, G, B that are arranged in line in the X-axis direction, and three pixel electrodes 41 opposite to the color filters 50, respectively, to form pixels PXs of three colors.

As illustrated in FIGS. 3 and 4, the active area AA of the CF substrate 30a includes the inner side where the light-shielding part (inter-pixel light-shielding part, black matrix) 52 for shielding light is formed. The light-shielding part 52 has pixel openings 52a that have substantially a grid planar shape so as to divide the adjacent pixels PXs (pixel electrodes 41) and transmit light to a position overlapped on the most part of the pixel electrodes 41 adjacent to the array substrate 30b in plan view. The plural pixel openings 52a are arranged in a matrix array along the X-axis direction and the Y-axis direction in the plate of the CF substrate 30a in the same manner as the pixel electrodes 41. Moreover, the light-shielding part 52 overlaps the gate lines 42 and the source lines 43 adjacent to the array substrate 30b in plan view.

As illustrated in FIG. 4, spacers 46 are disposed between both the substrates 30a, 30b in the active area AA for keeping a constant thickness of the liquid crystal layer 30C (cell gap, clearance). The spacers 46 are disposed adjacent to the upper layer of the common electrodes 44 in the array substrate 30b so as to penetrate the liquid crystal layer 30c, and contact the color filters 50 of the CF substrate 30a. Moreover, the spacers 46 are arranged on the color boundaries of the color filters 50. In addition, the both substrates 30a, 30b have innermost faces where alignment films 60a, 60b are formed, respectively, for alignment of the liquid crystal molecules contained in the liquid crystal layer 30c. Both the alignment films 60a, 60b are made of polyimide, for example, and are formed in a flat shape substantially entirely of at least the active area AA of the substrates 30a, 30b, respectively. Moreover, the CF substrate 30a may have a planate film formed between the alignment film 60a and the color filters 50.

Now description is made of various types of films laminated on the internal face of the array substrate 30b. As illustrated in FIG. 4, the glass substrate GS that forms the array substrate 30b includes, in this order from a lower layer side (glass substrate GS side), a first metal film (gate metal film, conductive film) 30bl, a gate insulating film 30b2, a semiconductor film 30b3, a second metal film (source material film, conductive film) 30b4, a planate film (insulating film, organic insulating film) 30b5, a first transparent electrode film (conductive film) 30b6, an interlayer insulating film (insulating film, inorganic insulating film) 30b7, a second transparent electrode film (conductive film) 30b8, and an organic insulating film 30b9.

The first metal film 30b1 and the second metal film 30b4 are each a single film made from one-type metal material or a laminated film made from different types of metal materials selected from Al, Cu, Ti, Mo, for example, or an alloy, thereby having conductivity and light-blocking property. Moreover, the first metal film 30b1 and the second metal film 30b4 are each arranged across the active area AA and the non-active area NAA. Among them, the first metal film 30b1 forms the gate line 42 and the gate electrode 40a of the TFT 40. The second metal film 30b4 forms the source line 43, and the source electrode 40b and the drain electrode 40c of the TFT 40. The gate insulating film 30b2 and the interlayer insulating film 30b7 are each made from an inorganic material such as silicon nitride (SiN_{X}) and silicon oxide (SiO₂). The gate insulating film 30b2 and the interlayer insulating film 30b7 keep insulation between the second metal film 30b4 and the second transparent electrode film 30b8 on the upper layer side and the first metal film 30b1 and the first transparent electrode film 30b6 on the lower layer side. The insulating films 30b2, 30b7 each made from the inorganic material are arranged across the active area AA and the non-active area NAA. The insulating films 30b2, 30b7 each made from the inorganic material have a thickness smaller than the planate film 30b5 and the organic insulating film 30b9 mentioned later. The planate film 30b5 and the organic insulating film 30b9 are made from the organic material such as an acrylic resin (e.g., polymethyl methacrylate (PMMA)). The planate film 30b5 functions planarization of steps generated on the lower layer side than itself. The organic insulating film 30b9 forms the spacers 46. The semiconductor film 30b3 is made of a thin film with a material of such as amorphous silicon and an oxide semiconductor. The semiconductor film 30b3 forms a channel (semiconductor part) 40d that is connected to the source electrode 40b and the drain electrode 40c in the TFT 40. The first transparent electrode film 30b6 and the second transparent electrode film 30b8 are each made of a transparent electrode material (e.g., Indium Tin Oxide (ITO) and Indium Zinc Oxide (IZO)), and are arranged across the active area AA and the non-active area NAA. Among them, the first transparent electrode film 30b6 forms the pixel electrode 41, whereas the second transparent electrode film 30b8 forms the common electrode 44.

Detailed description is made next of the configuration of the TFT 40 and the pixel electrode 41. As illustrated in FIG. 3, the drain electrode 40c is substantially L-shaped in plan view, and has a first end connected to the channel 40d so as to face the source electrode 40b, and a second end connected to the pixel electrode 41. The pixel electrode 41 formed by the first transparent electrode film 30b6 is composed of an electrode body 41a in a substantially parallelogram shape that overlaps the pixel opening 52a of the light-shielding part 52, and a contact part 41b that projects from the electrode body 41a toward the TFT 40 in the Y-axis direction. The contact part 41b is connected to the drain electrode 40c. The contact part 41b formed by the first transparent electrode film 30b6 and the drain electrode 40c formed by the second metal film 30b4 partially overlap each other, and overlapped portions thereof are connected to each other via contact holes 48 formed in the planate film 30b5 therebetween in an opened manner.

Configuration of Display Panel Manufacturing System

The display panel producing system 10 according to this embodiment is used in film formation of the alignment films 60a, 60b during producing of the paired substrates 30a, 30b of the liquid crystal panel 30 described above. The producing system 10 is especially effective for the film formation of the alignment film 60b in the uneven array substrate 30b due to the contact holes 48 and the spacers 46. The following describes the case where the alignment film 60b is formed on the array substrate 30b.

As described above, the producing system 10 illustrated in FIG. 1 is mainly composed of the ink-jet coating device 12 (hereinunder, simply referred to as a “coating device 12” occasionally) that applies the material of the alignment film 60b with the ink-jet technology to form the alignment film 60b. The producing system 10 includes the coating device 12, the measuring device 14 that measures the unevenness on the front face of the substrate, and the integrated control device 16 that controls the coating device 12 and the measuring device 14 integrally. In addition, such as a robot arm that is capable of moving while holding the substrate, which illustration is omitted, is included. The robot arm achieves loading and unloading of the substrate to and from the coating device 12 and the measuring device 14.

The ink-jet coating device 12 includes a transport device 12b for transporting the array substrate 30b in production that is fixed and held on the stage 12a, a coating head 12c that is disposed in an upper middle part of the transport device 12b, and a coating device controller 12d for controlling the transport device 12b and the coating head 12c. The coating device controller 12d performs control of a moving speed of the stage 12a on the transport device 12b. The coating head 12c has a plurality of nozzles for discharging the alignment film material, the nozzles being arranged at equal intervals perpendicularly with respect to a transportation direction of the transport device 12b. Moreover, the coating device controller 12d performs control of the coating head 12c in terms of an amount and timing (discharge time interval) of droplets discharged from the nozzles.

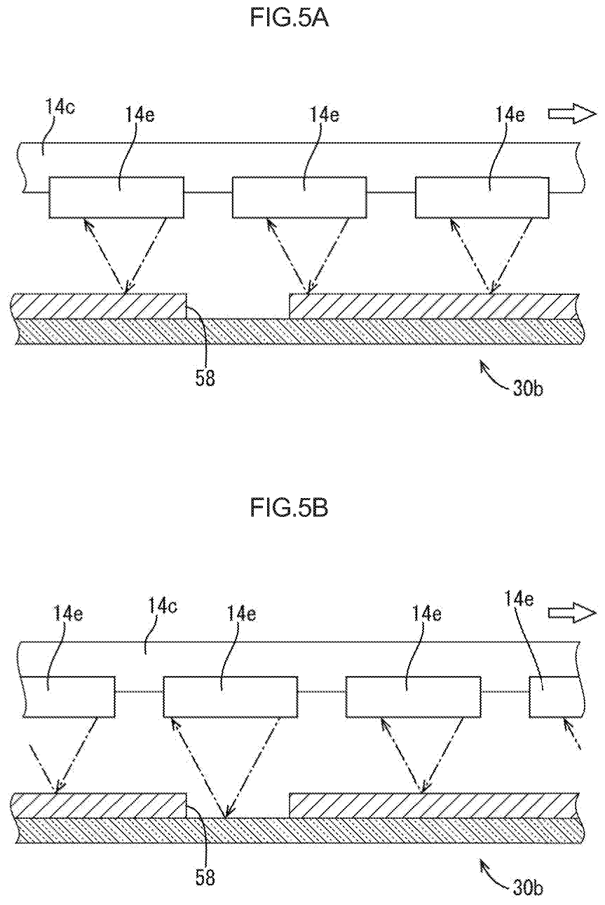

The measuring device 14 includes a transport device 14b for transporting the array substrate 30b in production that is fixed and held on the stage 14a, a measuring head 14c that is disposed in an upper middle part of the transport device 14b, and a measuring device controller 14d for controlling the transport device 14b and the measuring head 14c. The measuring head 14c has a plurality of laser displacement sensors 14e as a level sensor that are arranged at equal intervals perpendicularly with respect to the transportation direction (orthogonal transportation direction) of the transport device 14b. The laser displacement sensors 14e each apply laser beams to the measuring point, and receives the laser beams reflected on the measuring point, thereby detecting the level of the measuring point. Accordingly, the laser displacement sensors 14e allow detection of the level of the measuring point without contacting to the substrate. Moreover, as illustrated in FIGS. 5A and 5B, the measuring head 14c is movable perpendicularly with respect to the transportation direction of the transport device 14b. In other words, the measuring device 14 causes the transport device 14b to move the substrate in its transportation direction, and to move the measuring head 14c in the orthogonal transportation direction while causing the laser displacement sensors 14e to detect the levels of the measuring points on the substrate, thereby determining the unevenness of the substrate.

The integrated control device 16 is connected to the coating device controller 12d and the measuring device controller 14d to allow transmittance and receipt of various types of signals and data between the coating device controller 12d and the measuring device controller 14d. Controlling the coating device 12 and the measuring device 14 achieves control of producing the liquid crystal panel 30, particularly producing the array substrate 30b, more particularly film formation of the alignment film 60b of the array substrate 30b.

Drawback During Film Deposition with Ink-Jet Method

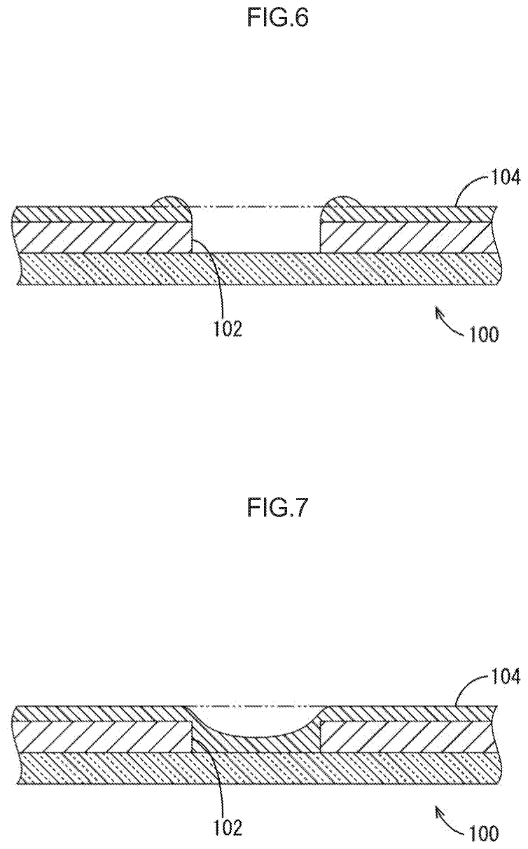

Now description is made of a drawback when the alignment film 60b of the array substrate 30b is formed with the currently-used method. As described above, the array substrate 30b has an uneven front face due to the contact holes 48 and the spacers 46. Such a case is assumed where a given amount of droplets is applied to a given position of the uneven base (at constant time intervals) by ink-jet coating. FIGS. 6 and 7 each illustrate one example in which an alignment film 104 is formed on a substrate 100 with a depression 102 by ink-jet coating. For instance, as illustrated in FIG. 6, such a case is considerable where an alignment film material insufficiently flows into the depression 102 to build up along edges that form the depression 102 of the substrate 100. Moreover, as illustrated in FIG. 7, such a case is also considerable where the alignment film material sucks into the depression 102. In this case, the alignment film 104 becomes thinner at the edges that form the depression 102 of the substrate 100, whereas the alignment film 104 is thicker from the center toward an inner wall (outward) in the depression 102. Moreover, another drawback similar to the case in FIGS. 6 and 7 may arise when the substrate 100 has some projection, which illustration is omitted. Then, if the alignment film 104 has the uneven film thickness as above, non-uniform display occurs on the manufactured liquid crystal panel.

Moreover, when the ink-jet coating has been currently performed for forming the alignment film, an amount or positions of droplets to be applied are determined under the assumption that a surface as a base is made in a designed shape. On the other hand, some deviation in design is occasionally present with respect to the surface of the substrate having a plurality of films laminated thereon prior to the ink-jet coating, leading to certain unevenness in film thickness around the projections and depressions on the substrate.

Method of Manufacturing Display Panel (Alignment Layer Forming Method)

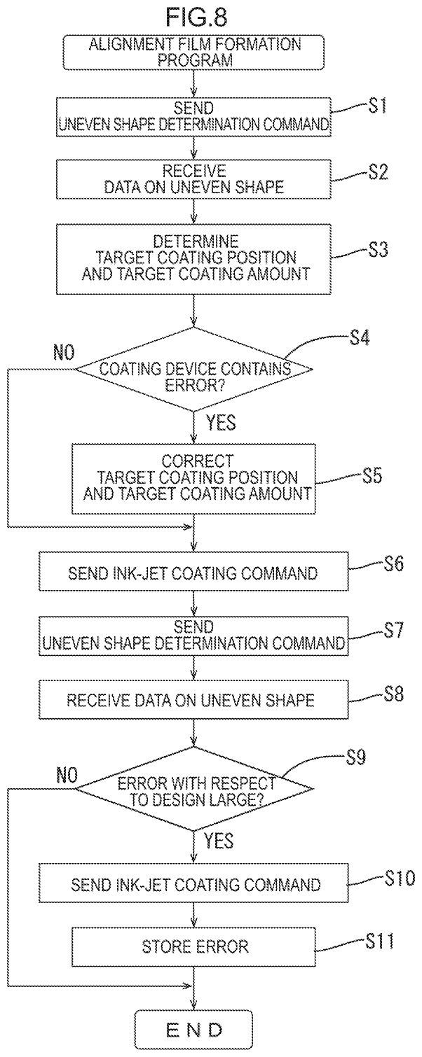

The producing system 10 allows suppression in uneven film thickness of the alignment film described above. The integrated control device 16 executes an alignment film formation program in FIG. 8, whereby producing the liquid crystal panel 30 with the suppressed non-uniform display, specifically producing the array substrate 30b with the suppressed unevenness in thickness of the alignment film is performed. The following describes in detail the producing method with the producing system 10 with reference to the flow chart of the alignment film formation program in FIG. 8.

(I) Measuring Step

The alignment film formation program includes Step 1 (hereinunder, occasionally abbreviated to “S1”, and other steps are likewise) in which an uneven shape determination command is firstly sent to the measuring device controller 14d so as to determine the uneven shape on the surface of the substrate loaded into the measuring device 14. If receiving the uneven shape determination command, the measuring device controller 14d performs control of the transport device 14b and the measuring head 14c to detect levels of measuring points, thereby obtaining the uneven shape on the surface of the substrate in accordance with the levels of the measuring points. Then, the measuring device controller 14d sends data on the obtained uneven shape to the integrated control device 16.

(II) Control Target Determining Step

Then, if receiving the data on the uneven shape of the substrate from the measuring device controller 14d in S2, the integrated control device 16 determines a target coating position and a target coating amount at the position of the determined substrate with the ink-jet technology in S3. Specifically, errors of the positions where the contact holes 48 or the spacers 46 are formed or designs in shape are recognized, and then the target coating position and the target coating amount are determined such that the alignment film 60b obtains the shape as illustrated, for example, by chain double-dashed lines in FIGS. 6 and 7. If it is detected that the coating device 12 itself contains errors about the coating position or the coating amount in an inspection step mentioned later, however, the target coating position and the target coating amount determined in S3 are correctable in S5.

(III) Inkjet Coating Step

If the target coating position and the target coating amount are determined, the target coating position and the target coating amount are sent to the coating device controller 12d, and ink-jet coating is performed to the substrate moved from the measuring device 14 into the coating device 12 in S6. Specifically, the coating device controller 12d determines a time interval and a discharge amount for nozzle discharge, and a speed of the transport device 12b moving the substrate in accordance with the received target coating position and the target coating amount, thereby performing control of the coating head 12c and the transport device 12b in accordance with target values of the target coating position and the target coating amount for forming the alignment film 60b.

(IV) Inspecting Step

If the alignment film 60b is formed and the array substrate 30b is completed, the array substrate 30b is moved back onto the measuring device 14. Then, the measuring device controller 14d receives an uneven shape determination command so as for the measuring device controller 14d to determine the uneven shape of the surface in S7. Accordingly, the measuring device 14 determines the uneven shape of the array substrate 30b. Then, if the data on the determined uneven shape of the array substrate 30b is received in S8, comparison is made in S9 between the determined shape of the array substrate 30b and the design shape to determine whether or not an error therebetween falls within a tolerance.

If the error of the surface shape of the array substrate 30b with respect to the design shape falls within the tolerance, the alignment film formation program for one array substrate 30b is finished. In contrast to this, if the error of the surface shape of the array substrate 30b with respect to the design shape does not fall within the tolerance, the array substrate 30b is moved back into the coating device 12 where the ink-jet coating is performed to a portion lacking the alignment film in S10. Then, if the error of the surface shape of the array substrate 30b with respect to the design shape does not fall within the tolerance, comparison is made between the measured data on the array substrate 30b measured in the inspection step and design data, and an error therebetween is stored in S11, whereby a one-time alignment film formation program is finished. Note that the stored error is used in subsequent program execution for correcting the target coating position and the target coating amount in S5.

With the display panel producing system 10 configured in such a manner as above, the positions and the depths of the projections and depressions on the substrate are recognized prior to the ink-jet coating, and then the film formation is performed by the ink-jet coating depending on the substrate. This suppresses unevenness in film thickness caused by the uneven shape. Moreover, the producing system 10 provides feedback of the error generated during the film formation by the ink-jet coating device 12 itself. Accordingly, the alignment film 60 is formable as designed than ever before, leading to prevention of the non-uniform display on the manufactured liquid crystal panel 30.

The producing system 10 forms the alignment film 60b of the array substrate 30b during producing of the liquid crystal panel 30. However, this is not limitative. Alternatively, the producing system (producing method) is applicable to coating with a material of a relatively lower viscosity with the ink-jet technology during producing of the array substrate or the CF substrate of the liquid crystal panel. Alternatively, the producing system (producing method) is applicable to formation of the organic electro luminescence (EL) layer during producing of the organic EL panel.

In the producing system 10 of the present embodiment, the integrated control device 16 that controls the coating device 12 and the measuring device 14 integrally functions as the control device. However, such a configuration is not limitative. For instance, the control device according to the technology described herein may be configured to include the coating device controller 12d and the measuring device controller 14d such that transmittance and receipt of data is performable between the coating device controller 12d of the coating device 12 and the measuring device controller 14c of the measuring device 14b.

### Second Embodiment

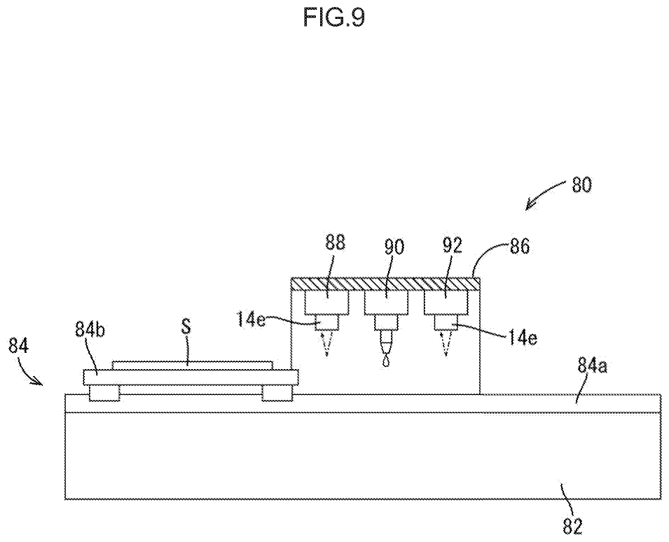

The display panel producing system 10 according to the first embodiment includes the ink-jet coating device 12 and the measuring device 14 individually. In contrast to this, a display panel producing system according to a second embodiment includes these units as one device. FIG. 9 illustrates a display panel producing device 80 (hereinafter, simply referred to as a “producing device 80” occasionally) as the display panel producing system in the second embodiment.

The producing device 80 conducts work similar to that of the producing system 10 in the first embodiment. That is, the producing device 80 forms the alignment film 60b of the array substrate 30b. The producing device 80 includes a base 82, a transport device 84 disposed on the base 82 for transporting a substrate S over the base 82, a frame 86 provided in the middle of the transport device 84 in a transportation direction across the transport device 84, and three work heads 88, 90, 92 provided on the frame 86 on an upper side of the transport device 84.

The transport device 84 includes a guide rail 84a, and a stage 84b that is movable on the guide rail 84a. The transport device 84 allows variation in moving speed of the stage 84b in the transportation direction. Here in FIG. 9, the stage 84b is positioned adjacent to a start position where the substrate S is loaded. The transport device 84 moves the stage 84b from the start position, and causes the three work heads 88, 90, 92 to conduct work to the substrate S.

The three work heads 88, 90, 92 are each, from the start position, a measuring head 88 that measures an uneven shape of the substrate S, a coating head 90 that applies an alignment film to the substrate S with an ink-jet process, and an inspecting head 92 that inspects a portion where the alignment film is formed. In this embodiment, the measuring head 88 and the inspecting head 92 have the same configuration, which is equal to that of the measuring head 14c of the measuring device 14 in the first embodiment. Moreover, the coating head 90 has the same configuration as that of the coating head 12c of the coating device 12 in the first embodiment.

In the producing device 80 configured in such a manner as above, the measuring head 88 allows measurement of a level of the substrate S, the coating head 90 allows ink-jet coating, and the inspecting head 92 allows measurement of the level of the substrate S simultaneously. Consequently, the producing device 80 allows film formation efficiently while suppressing unevenness in film thickness caused by the uneven shape.

1. A display panel producing system for producing a display panel including a substrate on which films are laminated, the display panel producing system comprising:
a measuring device configured to measure an uneven shape of a front face of the substrate in production;
an ink-jet coating device configured to apply a film formation material with an ink-jet technology to form the films on the substrate in the production; and
a control device configured to control the measuring device and the ink-jet coating device, wherein
the control device controls the measuring device to measure the uneven shape of the front face of the substrate in the production for formation of the films by the ink-jet coating device and to determine a control target for the formation of the films by the ink-jet coating device appropriate for the substrate on which measurement of the uneven shape is performed based on a result of the measurement.

2. The display panel producing system according to claim 1, wherein
the control device controls the measuring device to measure an uneven shape of a front face of the substrate with the films formed thereon by the ink-jet coating device to determine whether the films are properly formed by the ink-jet coating device.

3. The display panel producing system according to claim 2, wherein
if the films are not properly formed by the ink-jet coating device, the control device corrects the control target for later formation of films by the ink-jet coating device based on a difference between the uneven shape measured on the substrate on which the films are not properly formed and a target uneven shape.

4. The display panel producing system according to claim 1, wherein
the control device determines a target coating position of the film formation material with respect to the substrate in the production and a target coating amount at the position based on the result the measurement by the measuring device and controls the ink-jet coating device based on the target coating position and the target coating amount.

5. The display panel producing system according to claim 1, wherein
the ink-jet coating device includes a coating head with nozzles for discharging the film formation material, the nozzles discharging the film formation material while the coating head and the substrate in the production travel relative to each other to form the films, and
the control device determines at least one of a discharge amount, a discharge position, an interval of discharge for each of the nozzles and a relative traveling speed between the coating head and the substrate in the production in the ink-jet coating device.

6. The display panel producing system according to claim 1, wherein
the measuring device includes a level sensor that detects a level of a measuring point, and
the level sensor configured to detect a level of the substrate in the production to determine the uneven shape of the front face of the substrate.

7. The display panel producing system according to claim 6, wherein
the level sensor is a laser displacement sensor configured to receive laser beams applied to the measuring point and reflected at the measuring point to detect the level of the measuring point.

8. A method of producing a display panel including a substrate on which films are laminated, the method comprising:
a measuring step of measuring an uneven shape of a front face of the substrate in production;
a control target determining step of determining a control target for formation of the films with an ink-jet technology appropriate for the substrate on which measurement of the uneven shape is performed based on a result of the measurement in the measuring step to form the films on the substrate on which the measurement is performed with the ink-jet technology; and
an ink-jet coating step of coating the substrate in the production with a film formation material with the ink-jet technology based on the control target determined in the control target determining step.

9. The method of producing the display panel according to claim 8, further comprising:
an inspecting step of measuring an uneven shape of a front face of the substrate with the films formed thereon in the ink-jet coating step to determine whether the films are properly formed by the ink-jet coating device in the ink-jet coating step, wherein
the control target determining step includes correcting the control target based on a difference between the uneven shape of the substrate measured on the substrate on which the films are not properly formed and a target uneven shape to determine the control target if the inspecting step determines that the films are not properly formed in the ink-jet coating step.
